(19) United States
(12) Patent Application Publication
(10) Pub. No.: US 2021/0269150 A1
(43) Pub. Date: Sep. 2, 2021

(54) UNMANNED AERIAL VEHICLE

(71) Applicant: SZ DJI TECHNOLOGY CO., LTD., Shenzhen (CN)

(72) Inventors: Rongming XIONG, Shenzhen (CN); Xianwu XIONG, Shenzhen (CN); Yin TANG, Shenzhen (CN)

(21) Appl. No.: 17/130,995

(22) Filed: Dec. 22, 2020

Related U.S. Application Data
(63) Continuation of application No. PCT/CN2018/092935, filed on Jun. 26, 2018.

(51) Int. Cl. B64C 39/02; H05K 1/14; H05K 1/02; H05K 7/20

(52) U.S. Cl. CPC B64C 39/024; H05K 1/14; B64C 2201/027; H05K 7/20136; H05K 1/0201

(57) ABSTRACT

An unmanned aerial vehicle (UAV) includes a vehicle body and a plurality of functional structures. The vehicle body includes a plurality of support structures. The plurality of functional structures are arranged at the vehicle body independently of each other. The plurality of functional structures include a plurality of groups of functional structures corresponding to and arranged at the plurality of support structures.

### CROSS-REFERENCE TO RELATED APPLICATION

This application is a continuation of International Application No. PCT/CN2018/092935, filed on Jun. 26, 2018, the entire content of which is incorporated herein by reference.

### TECHNICAL FIELD

The present disclosure generally relates to the unmanned aerial vehicle (UAV) technology field and, more particularly, to a UAV.

### BACKGROUND

Unmanned aerial vehicle, abbreviated as UAV, is an unmanned aircraft operated by using a radio remote control device and a program controlled device or completely or intermittently autonomously operated by an onboard computer. With years of technology accumulation and development, UAVs have been applied to more and more application scenarios, for example, aerial photography, crop monitoring, vegetation protection, selfies, express transportation, disaster rescue, observation of wild animals, monitoring of infectious diseases, surveying and mapping, news reports, power inspections, filming, etc.

With continuous enlargement of the application fields of UAVs, users have imposed higher and higher application requirements on UAVs. In the existing technology, when a plurality of functional structures need to be arranged at a UAV, some functional structures need to be mounted in sequence. As such, if a functional structure with an earlier position in the mounting sequence is abnormal or needs to be replaced, other functional structures with later positions in the mounting sequence after that functional structure need to be detached, then that functional structure can be smoothly replaced or maintained. Therefore, the complexity and difficulty of replacing or maintaining the functional structures are increased.

### SUMMARY

Embodiments of the present disclosure provide an unmanned aerial vehicle (UAV) including a vehicle body and a plurality of functional structures. The vehicle body includes a plurality of support structures. The plurality of functional structures are arranged at the vehicle body independently of each other. The plurality of functional structures include a plurality of groups of functional structures corresponding to and arranged at the plurality of support structures.

### BRIEF DESCRIPTION OF THE DRAWINGS

FIG. 1 is a schematic exploded diagram of an unmanned aerial vehicle (UAV) according to some embodiments of the present disclosure.

FIG. 2 is another schematic exploded diagram of the UAV according to some embodiments of the present disclosure.

### REFERENCE NUMERALS

1 Vehicle body
10 Support structure
101 Upper housing structure
1011 Accommodation member
102 Lower housing structure
20 Functional structure
201 Sensing and detection structure
2011 First sensing and detection assembly
2012 Second sensing and detection assembly
2013 Third sensing and detection assembly
202 Gimbal assembly
203 PCBA assembly
2031 First PCBA
2032 Second PCBA
2033 Third PCBA
2034 Fourth PCBA
30 Middle frame structure
301 Frame body
303 Vehicle arm
40 Heat dissipation assembly
50 Power device

### DETAILED DESCRIPTION OF THE EMBODIMENTS

To make purposes, technical solutions, and advantages of embodiments of the present disclosure clearer, the technical solutions of embodiments of the present disclosure are described in detail in connection with the accompanying drawings of embodiments of the present disclosure. Described embodiments are some embodiments of the present disclosure but not all embodiments. Based on embodiments of the present disclosure, all other embodiments obtained by those of ordinary skill in the art without creative efforts are within the scope of the present disclosure.

In the present disclosure, the terms of “mount,” “connect,” “fix,” etc., should be understood broadly. For example, “connect” may be a fixed connection, a detachable connection, or an integral connection. For those of ordinary skill in the art, specific meanings of the above terms in the present disclosure may be understood according to a specific situation.

In the description of the present disclosure, the terms of “first” and “second” are only used to facilitate the description of different components, and should not be understood as indicating or implying the order relationship and relative importance or implicitly indicating a number of technical features. Thus, the feature associated with “first” and “second” may explicitly or implicitly include at least one of the feature.

Unless otherwise specified, all technical and scientific terms used herein have the same meaning as commonly understood by those skilled in the art of the present disclosure. The terms used in the description of the present disclosure are only for the purpose of describing specific embodiments and are not intended to limit the present disclosure.

Some embodiments of the present disclosure are described in detail in connection with the accompanying drawings. When no conflict exists between embodiments, following embodiments and features in embodiments may be combined with each other.

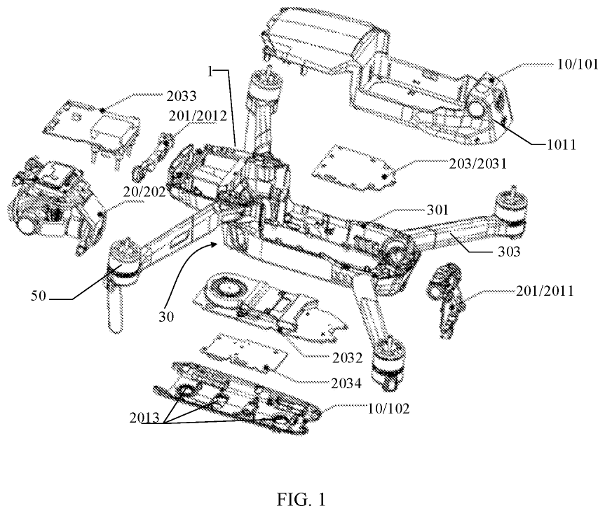

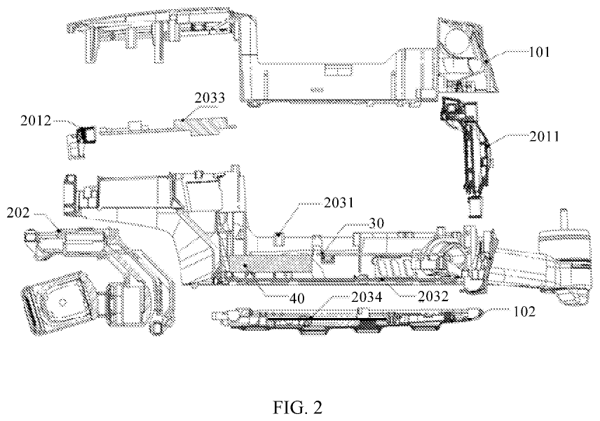

FIG. 1 is a schematic exploded diagram of an unmanned aerial vehicle (UAV) according to some embodiments of the present disclosure. FIG. 2 is another schematic exploded diagram of the UAV according to some embodiments of the present disclosure. As shown in FIG. 1 and FIG. 2, embodiments of the present disclosure provide the UAV, which includes a vehicle body 1 and a plurality of functional structures 20. The vehicle body 1 includes a plurality of support structures 10. The plurality of functional structures 20 are arranged at the vehicle body 1 independently of each other and are divided into a plurality of groups corresponding to the plurality of support structures 10 to be arranged at the corresponding support structures 10.

Components such as a controller, a power device 50, etc., may be arranged at the vehicle body 1. In some embodiments, the controller may be arranged at a corresponding support structure 10. The power device 50 may be arranged at a corresponding support structure 10. The controller may communicate with the power device 50.

In addition, the support structures 10 may be configured to support the functional structures 20 to mount the functional structures 20 at the vehicle body 1. A number of the support structures 10 included in the vehicle body 1 may not be limited by embodiments of the present disclosure. Those skilled in the art may set the number of the support structures 10 according to a design requirement. For example, the number of the support structures 10 may be set to two, three, four, etc., which is not repeated here.

Further, embodiments of the present disclosure may not limit a specific number and structure of the functional structures. Those skilled in the art may set the specific number and structure according to the specific design requirements. For example, the functional structures 20 may include a functional structure configured to realize image photography, a functional structure configured to realize image transmission, a functional structure configured to realize parameter detection, etc. In some embodiments, the functional structures 20 of embodiments of the present disclosure may include at least one of a Sensing and detection structure 201, a gimble assembly 202, or a printed circuit board assembly (PCBA) 203. The Sensing and detection structure 201 may be configured to realize detection functions such as image detection, distance detection, height detection, etc. The gimbal assembly 202 may include a gimbal configured to mount or fix an image collection device. The PCBA assembly 203 may include a plurality of functional circuits, which may be configured to realize functions such as data transmission, data processing, data communication, etc.

In some embodiments, no matter how many functional structures 20 are arranged, the plurality of functional structures 20 may be arranged independently of each other at the vehicle body 1. That is, a mounting operation and detaching operation between the functional structures 20 may not interfere with each other. Therefore, a sequence requirement may not be imposed on the mounting of the functional structures 20.

In the UAV consistent with embodiments of the present disclosure, by arranging the plurality of functional structures 20 independently of each other at the vehicle body 1, the mounting operation and the detaching operation between the functional structures 20 may not interfere with each other, and the sequence requirement may not be imposed to the mounting of the functional structures 20. As such, the complexity and difficulty may be reduced for performing the replacement or the maintenance operation on the functional structures 20, and the convenience and flexibility of using the UAV may be improved, which is beneficial to marketing and application.

Based on embodiments above, referring again to FIG. 1 and FIG. 2, specific structures of the support structures 10 are not limited in embodiments of the present disclosure. Those skilled in the art may set the specific structures of the support structures 10 according to a specific design requirement. In some embodiments, the plurality of support structures 10 at least may include an upper housing structure 101 and a lower housing structure 102 connected to the upper housing structure 101.

The functional structures 20 may be divided into two groups. One group may be arranged at the upper housing structure 101, and the other group may be arranged at the lower housing structure 102. Specific structures and quantities of the group of the functional structures 20 arranged at the upper housing structure 101 and the group of the functional structures 20 arranged at the lower housing structure 102 may not be limited, which may be set by those skilled in the art according to a specific design requirement. For example, the group of the functional structures 20 arranged at the upper housing structure 101 may include one, two, or three functional structures 20. The group of the functional structures 20 arranged at the lower housing structure 102 may include one, two, three, or four functional structures 20.

By dividing the functional structures 20 into the two groups with the one group arranged at the upper housing structure 101 and the other group arranged at the lower housing structure 102, arrangement structures and arrangement positions of the functional structures 20 may be simple and clear, which may facilitate the user to perform position and function recognition on the functional structures 20. Thus, the user's recognition efficiency of the functional structures 20 may be improved, and the complexity of the replacement and maintenance operation of the functional structures 20 performed by the user may be further reduced.

Further, in some embodiments, the support structure 10 of the vehicle body 1 includes a middle frame structure 30. The upper housing structure 101 may be arranged at an upper end of the middle frame structure 30 and detachably connected to the middle frame structure 30. The lower housing structure 102 may be arranged at a lower end of the middle frame structure 30 and detachably connected to the middle frame structure 30.

By arranging the middle frame structure 30 between the upper housing structure 101 and the lower housing structure 102, and detachably connecting the middle frame structure 30 to the upper housing structure 101 and the lower housing structure 102, the convenience of the mounting and detaching between the middle frame structure 30 and the upper housing structure 101 and the lower housing structure 102 may be effectively improved. In some embodiments, the middle frame structure 30 includes a frame body 301 and a plurality of vehicle arms 303 connected to the frame body 301. The plurality of vehicle arms 303 may be fixedly or rotatably connected to the frame body 301.

When the vehicle body 1 includes the middle frame structure 30, for a specific configuration manner of the PCBA assembly 203 of the functional structures 20, the PCBA assembly 203 may include a plurality of PCBAs arranged at the middle frame structure 30. The plurality of PCBAs arranged at the middle frame structure 30 include a first PCBA 2031, a second PCBA 2032, and a third PCBA 2033. The first PCBA 2031, the second PCBA 2032, and the third PCBA 2033 may be mounted at the middle frame structure 30 independently of each other.

In embodiments of the present disclosure, a specific mounting position and mounting manner of the first PCBA 2031 may not be limited, which may be determined by those skilled in the art according to a specific design requirement. In some embodiments, a first mounting member may be arranged at a top or inside of the middle frame structure 30. The first PCBA 2031 may be arranged at the first mounting member. In some embodiments, the first PCBA 2031 may be mounted at the first mounting member by a connector. The connector may include at least one of a screw, a bolt, a stud, etc. When being mounted, the first PCBA 2031 may be mounted at the first mounting member from the top to the bottom.

Similarly, in some embodiments, specific mounting positions and mounting manners of the second PCBA 2032 and the third PCBA 2033 may not be limited, which may be determined by those skilled in the art according to the specific design requirement. In some embodiments, for the third PCBA 2033, a second mounting member independent of the first mounting member may further be arranged at the top or inside of the middle frame structure 30. The third PCBA 2033 may be arranged at the second mounting member. When being mounted, the third PCBA 2033 may be mounted from the top to the bottom. For the second PCBA 2032, a third mounting member may be arranged at the bottom or inside of the middle frame structure 30. The second PCBA 2032 may be arranged at the third mounting member. When being mounted, the second PCBA 2032 may be mounted at the third mounting member from the bottom to the top.

The second mounting member may be arranged at the front end of the first mounting member. The third mounting member may be arranged at the bottom end of the first mounting member. Positions may be defined as follows: a direction, in which a vehicle head of the UAV is arranged, may be determined as the front end, and a direction, in which a vehicle tail of the UAV is arranged, may be determined as the rear end. A gimbal assembly 202 may be arranged at a position close to the vehicle head of the UAV. Therefore, the front end and the rear end of the UAV may be determined according to the position where a gimbal is arranged.

By mounting the first PCBA 2031, the second PCBA 2032, and the third PCBA 2033 independently of each other at the middle frame structure 30, mounting processes of the first PCBA 2031, the second PCBA 2032, and the third PCBA 2033 may not interfere with each other. That is, elements may be detached or mounted at their mounting positions without interfering with each other. Thus, elements may not include portions overlapping or interacting with each other. For example, the first PCBA 2031 and the second PCBA 2032 may be arranged at two portions of the middle frame structure 30. However, mounting independently does not mean that the first PCBA 2031, the second PCBA 2032, and the third PCBA 2033 are not connected to each other at all. For example, the independently mounted first PCBA 2031 and the second PCBA 2032 may communicate with/be electrically connected to each other. The independently mounted first PCBA 2031 and the third PCBA 2033 may communicate with/be electrically connected to each other.

In some embodiments, the first PCBA 2031 may include an electric speed control (ESC) board, which may be configured to control the power device 50 to control a flight attitude of the UAV. The flight attitude may include flight height, flight speed, flight direction, etc. In some embodiments, the power device 50 may include a propeller and a motor. The motor may be configured to drive the propeller to rotate. Thus, a controller may control the rotation speed of the motor to adjust the flight attitude. The second PCBA 2032 may include functional circuits for image transfer, vision, radiofrequency, which may be configured to process corresponding information. The third PCBA 2033 may include a global positioning system (GPS) board, which includes a GPS circuit.

In addition, for the PCBA assembly 203, the PCBA assembly 203 further includes a fourth PCBA 2034. The fourth PCBA 2034 may be mounted at an inner side of the lower housing structure 102. Thus, a position of arranging the fourth PCBA 2034 may be different from the positions of arranging the above-described three PCBAs. As such, when a user performs adjustment or replacement on a certain or some PCBAs of the PCBA assembly 203, a corresponding PCBA may be directly positioned or recognized. Thus, the efficiency of the replacement and recognition may be improved.

In some embodiments, the fourth PCBA 2034 may include an infrared time of flight (TOF) processing circuit.

In some embodiments, the PCBAs of the PCBA assembly 203 may have other functions, which may be adjusted according to actual needs.

Based on embodiments above, referring again to FIG. 1 and FIG. 2, a specific structure of the Sensing and detection structure 201 is not limited by embodiments of the present disclosure. Those skilled in the art may set the structure of the Sensing and detection structure 201 according to a specific design requirement. In some embodiments, the Sensing and detection structure 201 may include at least one sensing and detection assembly arranged at the middle frame structure 30.

A sensing and detection assembly may include at least one of a vision sensor or a distance sensor. The at least one sensing and detection assembly may include a first sensing and detection assembly 2011 and a second sensing and detection assembly 2012. The first sensing and detection assembly 2011 and the second sensing and detection assembly 2012 may be independently mounted at the middle frame structure 30.

In some embodiments, the middle frame structure 30 may further include a first assembly mounting member and a second assembly mounting member that are independent of each other. The first sensing and detection assembly 2011 may be arranged at the first assembly mounting member, and the second sensing and detection assembly 2012 may be arranged at the second assembly mounting member. When being mounted, the first sensing and detection assembly 2011 may be mounted at the first assembly mounting member from the top to the bottom. The second sensing and detection assembly 2012 may be mounted at the second assembly mounting member from the top to the bottom. Thus, the first sensing and detection assembly 2011 and the second sensing and detection assembly 2012 may be fixed at the first assembly mounting member and the second assembly mounting member by connectors, respectively. The connectors may include screws, bolts, studs, etc.

In some embodiments, two independent mounting members may not be two parts that are not connected at all, as long as no interference of mounting and detaching elements at the two mounting positions is ensured. That is, as long as no overlapping is ensured between the two mounting members. For example, the two mounting members may be two portions of a large frame.

Further, the first assembly mounting member may be arranged at a rear portion of the middle frame structure 30. The second assembly mounting member may be arranged at a front portion of the middle frame structure 30. As such, the first sensing and detection assembly 2011 and the second sensing and detection assembly 2012 may be mounted at the middle frame structure 30 independently of each other through the first assembly mounting member and the second assembly mounting member.

For the first sensing and detection assembly 2011, a portion of the first sensing and detection assembly 2011 may be arranged at the upper housing structure 101. In some embodiments, the upper housing structure 101 may include an accommodation member 1011. The first sensing and detection assembly 2011 may be partially accommodated in the accommodation member 1011 of the upper housing structure 101.

Further, the Sensing and detection structure 201 further includes a third sensing and detection assembly 2013. The third sensing and detection assembly 2013 is arranged at the lower housing structure 102. The third sensing and detection assembly 2013 may include a vision sensor, a TOF sensor, an ultrasound wave, etc. One or two vision sensors may be included. In some embodiments, the vision sensor and the distance sensor may be arranged at the lower housing structure 102 in sequence, and an additional searchlight may be arranged at the lower housing structure 102.

In some embodiments, for the gimbal assembly 202, the middle frame structure 30 may further include a gimbal mounting member. The gimbal assembly 202 may be mounted at the gimbal mounting member. The gimbal mounting member may be arranged at the front portion of the middle frame structure 30.

The gimbal assembly 202 may be mounted at the gimbal mounting member by a connector. The connector may include a screw, a bolt, a stud, etc. When being mounted, the gimbal assembly 202 may be mounted at the gimbal mounting member from the bottom to the top and then be fixed by the connector. Thus, the gimbal assembly 202 may be mounted at the front portion of the middle frame structure 30. The gimbal assembly 202 may be ensured to be detached and mounted conveniently, while stability and reliability of mounting the gimbal assembly 202 may be effectively guaranteed, and the safety and reliability of the UAV application may be further improved. In addition, the gimbal assembly 202 may be mounted at the gimbal mounting member by a fast-detachable snap buckle.

For the UAV consistent with embodiments of the present disclosure, the functional structures 20 may be designed in modular by ensuring that a volume of the vehicle body of the UAV is small enough to realize the independent mounting. Thus, the functional structures 20 may be mounted independently of each other, and a mandatory sequence constraint may not be imposed. Therefore, when a functional structure 20 needs to be replaced, the functional structure 20 may be detached independently, which may be conveniently mounted and repaired to effectively improve the convenience and flexibility of the UAV application. For those elements that may block each other, for example, the second PCBA 2032 and the fourth PCBA 2034, by arranging the second PCBA 2032 and the fourth PCBA 2034 at the middle frame structure 30 and the lower housing structure 102, respectively, the two PCBAs that may block each other may be ensured to be separated when the lower housing structure 102 is separated from the middle frame structure 30. Thus, if one of the PCBAs fails, the other one of the PCBAs may not need to be detached first to repair the PCBA.

Based on embodiments above, referring again to FIG. 1 and FIG. 2, when the first PCBA 2031 and the second PCBA 2032 are used, the first PCBA 2031 and the second PCBA 2032 may generate heat. In some embodiments, to avoid a situation that overheating may cause the first PCBA 2031 and the second PCBA 2032 to fail, a heat dissipation assembly 40 is arranged between the first PCBA 2031 and the second PCBA 2032.

The heat dissipation assembly 40 may include a fan and a heat dissipation component. To ensure that the volume of the vehicle body 1 is small enough and reduce a space taken by the heat dissipation assembly 40, the fan of the heat dissipation assembly 40 may include a micro fan. The micro fan may have a small volume. The heat dissipation component may be arranged at the right side of the fan. A fin plate may be arranged in the heat dissipation component. The heat dissipation component may lead the generated heat to an air outlet of the vehicle body 1. The fan may be mounted at the second PCBA 2032. In some embodiments, the fan may be adhered to the second PCBA 2032 by adhesive.

By using the heat dissipation assembly 40 arranged between the first PCBA 2031 and the second PCBA 2032 to lead the generated heat to the air outlet of the vehicle body 1, an environment temperature of the first PCBA 2031 and the second PCBA 2032 may be effectively ensured not to be too high. Thus, the stability and reliability of the operation of the first PCBA 2031 and the second PCBA 2032 may be ensured to further improve the safety of the UAV application.

The technical solutions and technical features in embodiments above may be individual or combined with no conflict with the present disclosure. As long as the technical solutions and technical features do not exceed the understanding scope of those skilled in the art, the technical solutions and the technical features all belong to equivalent embodiments within the scope of the present disclosure.

In some embodiments of the present disclosure, the disclosed related devices and methods may be implemented in other manners. For example, the device embodiments described above are merely illustrative. For example, the division of the modules or units is only a logical functional division, and other divisions may exist in practical applications. For example, a plurality of units or components may be combined or can be integrated into another system, or some features may be ignored or not implemented. In addition, the displayed or discussed mutual coupling or direct coupling or communication may include indirect coupling or communication through some interfaces, devices, or units, and may be in electrical, mechanical, or other forms.

The units described as separate components may or may not be physically separated, and the components displayed as units may or may not be physical units. That is, the components or units may be located at one place, or may be distributed in a plurality of network units. Some or all of the units may be selected according to actual needs to achieve the objectives of the solutions of embodiments of the present disclosure.

The above description is only embodiments of the present disclosure, and do not limit the scope of the present disclosure. Any equivalent structure or equivalent process variation made by using the content of the description and drawings of the present disclosure may be directly or indirectly applied to other related technical fields, which are within the scope of the present disclosure.

In summary, above embodiments are only used to illustrate the technical solutions of the present disclosure, but not to limit it. Although the present disclosure is described in detail with reference to embodiments above, those of ordinary skill in the art should understand that modifications may still be made to the technical solutions described in embodiments, or equivalent replacements may be made to some or all of the technical features. These modifications or replacements do not make the essence of the corresponding technical solutions depart from the scope of the technical solutions of embodiments of the present disclosure.

What is claimed is:

1. An unmanned aerial vehicle (UAV) comprising:
a vehicle body including a plurality of support structures; and
a plurality of functional structures arranged at the vehicle body independently of each other, the plurality of functional structures including a plurality of groups of functional structures corresponding to and arranged at the plurality of support structures.

2. The UAV of claim 1, wherein the plurality of support structures include:
an upper housing structure; and
a lower housing structure connected to the upper housing structure.

3. The UAV of claim 2, wherein:
the plurality of groups include two groups of functional structures;
one of the two groups is arranged at the upper housing structure; and
another one of the two groups is arranged at the lower housing structure.

4. The UAV of claim 2, further comprising:
a middle frame structure;
wherein:
the upper housing structure is arranged at an upper end of the middle frame structure and is detachably connected to the middle frame structure; and
the lower housing structure is arranged at a bottom end of the middle frame structure and is detachably connected to the middle frame structure.

5. The UAV of claim 4, wherein the plurality of functional structures include at least one of a Sensing and detection structure, a gimbal assembly, or a printed circuit board assembly (PCBA) assembly.

6. The UAV of claim 5, wherein the PCBA assembly includes a plurality of PCBAs arranged at the middle frame structure.

7. The UAV of claim 6, wherein the plurality of PCBAs arranged at the middle frame structure include a first PCBA, a second PCBA, and a third PCBA arranged at the middle frame structure independently of each other.

8. The UAV of claim 7, wherein:
a mounting member is arranged at a top of or inside the middle frame structure; and
the first PCBA is arranged at the mounting member.

9. The UAV of claim 8, wherein:
the mounting member is a first mounting member;
a second mounting member independent of the first mounting member is arranged at the top of or inside the middle frame structure; and
the third PCBA is arranged at the second mounting member.

10. The UAV of claim 9, wherein the second mounting member is arranged at a front end of the first mounting member.

11. The UAV of claim 7, wherein:
a mounting member is arranged at a bottom of or inside the middle frame structure; and
the second PCBA is arranged at the mounting member.

12. The UAV of claim 7, wherein a heat dissipation assembly is arranged between the first PCBA and the second PCBA.

13. The UAV of claim 12, wherein the heat dissipation assembly includes a fan and a heat dissipation component.

14. The UAV of claim 13, wherein the fan is mounted at the second PCBA.

15. The UAV of claim 6, wherein the PCBA assembly further includes a fourth PCBA arranged at an inner side of the lower housing structure.

16. The UAV of claim 5, wherein the Sensing and detection structure includes at least one sensing and detection assembly arranged at the middle frame structure.

17. The UAV of claim 16, wherein:
the at least one sensing and detection assembly arranged at the middle frame structure includes a first sensing and detection assembly and a second sensing and detection assembly mounted at the middle frame structure independently of each other.

18. The UAV of claim 17, wherein:
the middle frame structure includes a first assembly mounting member and a second assembly mounting member independent of each other;
the first sensing and detection assembly is arranged at the first assembly mounting member; and
the second sensing and detection assembly is arranged at the second assembly mounting member.

19. The UAV of claim 18, wherein:
the first assembly mounting member is arranged at a rear portion of the middle frame structure; and
the second assembly mounting member is arranged at a front portion of the middle frame structure.

20. The UAV of claim 17, wherein:
the upper housing structure includes an accommodation member; and
the first sensing and detection assembly is partially accommodated in the accommodation member of the upper housing structure.

21. The UAV of claim 16, wherein the Sensing and detection structure includes a sensing and detection assembly arranged at the lower housing structure.

22. The UAV of claim 5, wherein:
the middle frame structure further includes a gimbal mounting member; and
the gimbal assembly is mounted at the gimbal mounting member.

23. The UAV of claim 22, wherein the gimbal mounting member is arranged at a front portion of the middle frame structure.
